(19) United States
(12) Patent Application Publication
(10) Pub. No.: US 2011/0274837 A1
(43) Pub. Date: Nov. 10, 2011

(54) ALD REACTOR, METHOD FOR LOADING ALD REACTOR, AND PRODUCTION LINE

(75) Inventors: Pekka Soininen, Helsinki (FI); Jarmo Skarp, Espoo (FI)

(73) Assignee: BENEQ OY, VANTAA (FI)

(21) Appl. No.: 13/143,317

(22) PCT Filed: Feb. 8, 2010
(86) PCT No.: PCT/FI2010/050080

§ 371 Date: Jul. 5, 2011

(30) Foreign Application Priority Data
Feb. 9, 2009 (FI) 20095126

(51) Int. Cl. C23C 16/458; B65G 47/74; C23C 16/455

(52) U.S. Cl. 427/248.1; 118/728; 118/729; 118/733; 118/719; 414/806

(57) ABSTRACT

An ALD reactor for treating one or more substrates is provided. The ALD reactor includes at least one reaction chamber which has a front plate including gas connections for introducing starting materials, flushing gases and the like gases into the reaction chamber. In addition, the front plate is arranged for being placed over the substrate for closing the reaction chamber and at distance from the substrate surface for opening the reaction chamber such that the substrate is arranged for being loaded below, above or in front of the front plate, when the reaction chamber is in the open state, in which the front plate is at a distance from the substrate and such that the substrate is treatable by the ALD method in the closed state of the reaction chamber, in which the front plate is placed onto the substrate.

### BACKGROUND OF THE INVENTION

The invention relates to an ALD reactor in accordance with the preamble of claim 1 and in particular to an ALD reactor for treating one or more substrates, the ALD reactor comprising at least one reaction chamber including a front plate having gas connections for feeding starting materials, flushing gases and the like gases inside the reaction chamber. The invention also relates to a production line in accordance with the preamble of claim 26 and in particular to a production line which comprises two or more successive process chambers for modifying and/or growing a substrate surface and in which the substrate is carried in horizontal direction through the successive process chambers. The invention further relates to a method in accordance with the preamble of claim 27 and in particular to a method for loading one or more substrates into the reaction chamber of the ALD reactor and removing them therefrom.

In accordance with the prior art, the substrates are loaded into an atomic layer deposition reactor, an ALD reactor, and in particular into its reaction chamber locating inside a low-pressure chamber, and they are removed therefrom through a gate valve, or alternatively, the reaction chamber has an openable cover through which the substrate may be placed in the reaction chamber. In that case each substrate is loaded into the ALD reactor and removed therefrom separately such that the loading/removal consists of a plurality of successive operations or movements, which are performed in a predetermined order.

A problem with the above described arrangement is that complicated and slow solutions for loading a substrate into the reaction chamber make it difficult to utilize the ALD method in connection with production lines. Complicated prior art solutions are slow and require complicated devices for manipulating the substrates when they are loaded into and removed from the reaction chamber by means of several successive movements. In addition, the prior art solutions do not enable a quick and efficient manner of operating the ALD reactor using a flow-through principle such that a substrate may be received from one production stage into the ALD reactor and transferred further to a subsequent production stage after the ALD reactor.

### BRIEF DESCRIPTION OF THE INVENTION

The object of the invention is to provide an ALD reactor, a method for loading the ALD reactor and a production line such that the above problems may be solved. This is achieved by an ALD reactor in accordance with the characterizing part of claim 1, which is characterized in that a front plate is arranged for being placed over the substrate for closing the reaction chamber and at a distance from the substrate for opening the reaction chamber such that the substrate is arranged for being loaded beneath, above or in front of the front plate when the reaction chamber is in an open state, in which the front plate is at a distance from the substrate, and such that the substrate is treatable with the ALD method in the closed state of the reaction chamber, in which the front plate is placed over the substrate. The objects of the invention are further achieved by a production line in accordance with the characterizing part of claim 26. The objects of the invention are still further achieved by a method in accordance with the characterizing part of claim 27, which is characterized in that in the method the substrate is loaded into the reaction chamber for treatment:

by transferring the substrate above, beneath or in front of the front plate of the reaction chamber, the front plate including gas connections for feeding starting materials, flushing gases and the like gases inside the reaction chamber; and

by moving the front plate of the reaction chamber and the substrate with respect to one another in order to place the front plate on the substrate for closing the reaction chamber to a closed state;

and that in the method the substrate is removed from the reaction chamber:

by moving the front plate of the reaction chamber and the substrate with respect to one another in order to place the front plate and the substrate at a distance from one another for opening the reaction chamber to an open state; and

by transferring the substrate away from above, beneath or in front of the front plate of the open-state reaction chamber.

The preferred embodiments of the invention are disclosed in the dependent claims.

The invention is based on the idea that the reaction chamber provided inside a low-pressure chamber of an ALD reactor intended for an atomic layer deposition method (ALD method) is formed to have a structure that a substrate is transferrable in horizontal direction beneath or above a front plate, through which starting materials, flushing gases and other gases are fed, and the substrate and the front plate are movable with respect to one another in order to place the front plate on the substrate surface for closing the reaction chamber. The reaction chamber may thus be set in an open position, in which the front plate is at a distance from the substrate surface above or beneath the substrate. In the open state of the reaction chamber the substrate is trans-ferrable above or beneath the front plate and removable therefrom. In order to close the reaction chamber the front plate and the substrate are moved with respect to one another such that the front plate is placed over the substrate surface to be treated. The relative movement of the substrate and the front plate may be implemented by moving either the front plate or the substrate, or both. When the upper surface of the substrate is treated, the front plate may be lowered from up downwards onto the upper surface of the substrate, or the substrate may be lifted upwards so as to place the front plate onto the substrate surface. Alternatively, the substrate may be lifted upwards and at the same time the front plate may be lowered downwards. When the lower surface of the substrate is treated, the front plate may be lifted upwards to place the front plate on the lower surface of the substrate. The upper face and the lower face of the substrate may be treated both at the same time as described above by providing the reaction chamber with two front plates, which are placed above and beneath the substrate, respectively, whereby the substrate is sandwiched between the front plates. In that case both front plates may be moved in relation to the substrate so as to close the reaction chamber.

Even though it is described in the examples of the present invention that the front and support structures are arranged movable in relation to one another substantially in vertical direction, the front plate and the substrate may also be arranged movable in relation to one another substantially in horizontal direction, for instance. In that case a large glass plate, for instance, which is carried in an upright position, may be transferred in front of the front plate at a distance therefrom such that the front plate and the substrate are movable in horizontal direction with respect to one another to close the reaction chamber, whereby the glass plate is placed in the upright position on the front plate. Correspondingly, the reaction chamber may be opened by means of a relative, horizontal movement of the front plate and the substrate.

An advantage of the method and the system of the invention is that it simplifies the loading of the substrate, in particular a plate-form or planar substrate, into the reaction chamber of the ALD reactor. In accordance with the invention, the opening and the closing of the reaction chamber may be performed by one movement or a relative movement in one direction. Advantageously, in connection with the closing of the reaction chamber it is possible to transfer the substrate into the reaction chamber and enclose it therein, and correspondingly, remove it from the reaction chamber in connection with the opening thereof. Thus, the structure of the reaction chamber is made simple, and correspondingly, the loading of the substrate into the reaction chamber and removal therefrom are made simple and fast, when the closing of the reaction chamber and the loading of the substrate into the reaction chamber are carried out simultaneously by one movement, and correspondingly, the opening of the reaction chamber and the removal of the substrate from the reaction chamber are carried out by one movement, preferably by a movement in one direction. The present invention also has an advantage that the substrate, and optionally also a substrate support, detaches from the conveyor track, whereby no separate movement and force control are needed for upper and lower sealings, the conveyor track is not loaded with closing force, and the conveyor track, such as conveyor belt, may be used for other transfer purposes.

### BRIEF DESCRIPTION OF THE DRAWINGS

In the following, the invention will be described in greater detail in connection with preferred embodiments, with reference to the attached drawings, in which

FIGS. 1A and 1B show an ALD reactor of the invention and

FIG. 2 shows a reaction chamber of the ALD reactor of the invention.

### DETAILED DESCRIPTION OF THE INVENTION

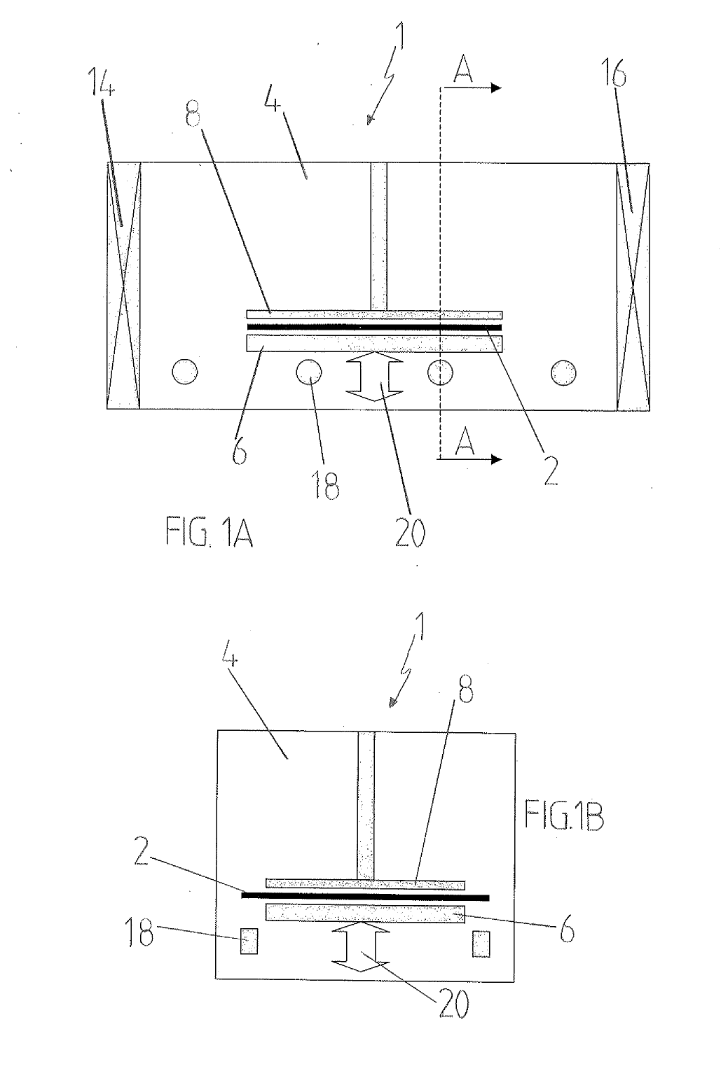

With reference to FIG. 1A, there is shown an embodiment of an ALD reactor 1 in accordance with the present invention. The ALD reactor 1 of FIG. 1A is designed such that it may be installed to form a part of a production line, which comprises two or more successively mounted process chambers, through which a substrate passes during a production process. The ALD reactor 1 of FIG. 1A comprises a process chamber 4 and a first gate arrangement 14 and a second gate arrangement 16. The process chamber 4 may be e.g. a low-pressure chamber, a high-pressure chamber, or a normal atmospheric pressure chamber (NTP: 1 bar, 0° C.). The gate arrangements 14, 16 may comprise a gate valve or another corresponding parting device, through which the substrate 2 is introduced into the low-pressure chamber 4 of the ALD reactor 1 and removed therefrom. In accordance with FIG. 1A, the ALD reactor 1 further comprises transfer means 18 for transferring the substrate 2 inside the low-pressure chamber 4 as well as into and out of the low-pressure chamber 4. The transfer means 18 may be, for instance, rolling conveyance wheels or conveyance tracks or conveyance belts, onto which the substrate 2 is transferred. In accordance with FIG. 1B, the transfer means 18 are provided such that the substrate 2 is supported thereto only at its opposing edges or edge areas, in other words, the substrate 2 is placed on the transfer means 18 such that only the edges of the substrate 2 come into contact with the transfer means 18 when the substrate 2 is placed on the transfer means 18. However, it should be noted that even though this specification generally deals with planar substrates, the substrates may also be any other pieces, such as mobile phone skins, or the like, that have been placed one or more on a substrate support.

In this specification, the substrate 2 refers to a substrate alone, or alternatively, both to the actual substrate and the substrate support, to which the substrate is supported or attached during the manufacturing/modifying process. Thus, in the solution of FIGS. 1A and 1B a substantially planar 2 may be placed onto transfer means 18 such that only the substrate support comes into contact with the transfer means 18 and the actual substrate is located between the transfer means 18. FIG. 1B shows how the transfer means 18 are positioned in relation to the substrate 2 such that they are able to support the substrate 2 from beneath only at the edges of the substrate 2.

In the solution of FIG. 1A the substrate 2 may be introduced into the low-pressure chamber 4 of the ALD reactor 1 via the gate arrangement 14 and the substrate 2 may be further transferred within the low-pressure chamber 4 by means of the transfer means 18. Inside the low-pressure chamber 4 there is further provided a reaction chamber that comprises a front plate 6 and a support structure 8 in accordance with FIG. 1A. It should be noted, however, that in some embodiments the low-pressure chamber may be omitted or it may be replaced by some other, corresponding process chamber, such as a high-pressure chamber or a normal pressure chamber (NTP: 1 bar, 0° C.). In the embodiment described herein, the process chamber is implemented as a low-pressure chamber, but it may also be replaced by another process chamber. The stack in the reaction chamber consisting of the front plate 6 and the support structure 8 is provided to be opened such that the front plate 6 and the support structure 8 are mutually movable in order to be placed at a distance from one another and against one another. The front plate 6 and the support structure 8 are provided movable substantially perpendicularly to their plate surfaces. In the solution of FIGS. 1A and 1B the front plate 6 and the support structure 8 are provided movable in a substantially vertical direction with respect to one another for opening and closing the reaction chamber. In accordance with FIGS. 1A and 1B, the reaction chamber is closed by moving the front plate 6 and the support structure 8 mutually towards one another such that the substrate 2 will be sandwiched between the front plate 6 and the support structure 8. In the closed state of the reaction chamber the front plate 6 and the support structure 8 may be placed against one another, or alternatively, they may be placed against the substrate 2 and/or the substrate support on the opposite sides thereof such that the substrate 2 or the substrate support constitutes a part of the reaction chamber when the reaction chamber is closed. Correspondingly, the reaction chamber is opened by moving the front plate 6 and the support structure 8 mutually away from one another. In the present invention, it should be further noted that when the substrate is referred to as being loaded between the front plate and the support structure it also includes the alternative in which the support structure is a substrate support and always follows the substrate. In that case the loading of the substrate between the front plate and the support structure is carried out by transferring the support structure, and the substrate thereon, to be in alignment with the front plate such that the substrate is between the front plate and the support structure. In other words, the substrate is not inserted between the front plate and the support structure, but it will remain between the front plate and the support structure when the support structure, i.e. the substrate support, becomes substantially in alignment with the front plate, for instance, beneath the front plate.

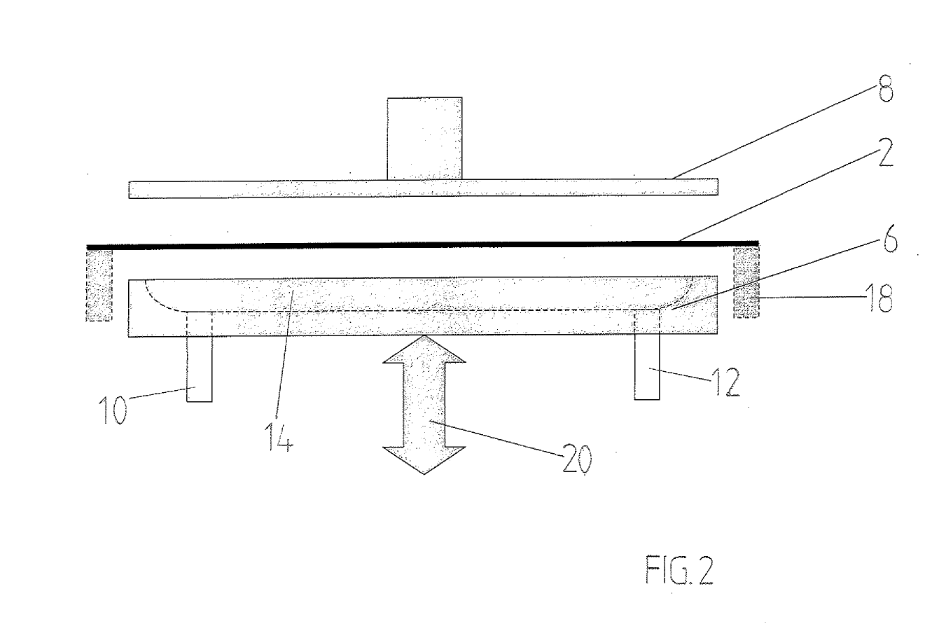

The reaction chamber in accordance with the present invention is described in greater detail in FIG. 2. In this connection the front plate 6 of the reaction chamber refers to that part of the reaction chamber which includes gas connections 10, 12 for feeding starting materials, flushing gases and the like gases into the reaction chamber and optionally for removing them from the reaction chamber. In other words, gas changes of the reaction chamber are carried out through the gas connections 10, 12 in the front plate in accordance with the principles of the ALD method. In FIG. 2, gases may be fed through an inlet connection 10 and removed through an outlet connection 12, respectively. The front plate 6 further comprises feed openings (not shown) for feeding gases into the reaction chamber and discharge openings for removing gases from the reaction chamber. In a preferred solution the feed openings and the discharge openings are provided such that each side wall of the front plate 6 comprises at least one feed opening and/or discharge opening. In that case, when the reaction chamber is closed, all its side walls participate in gas change, each side wall being provided with one or more feed and/or discharge openings. It is advantageous to solve this by dividing the periphery consisting of the side walls of the reaction chamber into one or more feeding sections, wherefrom gases are to be fed into the reaction chamber, and into one or more discharge sections, wherefrom gases are to be removed from the reaction chamber. According to FIG. 2, the front plate 6 is provided concave so as to form a reaction space 24 inside the reaction chamber. The front plate 6 being concave, the front plate and the substrate 2 placed against it or the substrate 2 together with the substrate support define the reaction space 24, whereby the reaction space 24 is formed between the front plate 6 and the substrate 2 in accordance with FIG. 2. In this case the substrate 2 or the substrate 2 and its support constitute a part of the reaction chamber, when the reaction chamber is in the closed state. The reaction chamber may further be dimensioned or arranged to receive two or more substrates 2 at the same time. In that case, the reaction chamber being in the open state, two or more substrates 2 are transferred between the front plate 6 and the support structure 8, whereafter the reaction chamber is closed such that these two or more substrates 2 remain at least for the portion to be processed inside the reaction chamber as described above. In a preferred solution the reaction chamber is arranged to receive two or more substrates 2 in juxtaposition. In that case the feeding and removal of gases may be arranged in the reaction chamber such that the feed openings are placed in the front plate 6 at the locations between the substrates 2 and the discharge openings in the side walls of the front plate 6 surrounding the substrates 2 in the vicinity of edge areas of the substrates 2. Thus, for instance in the solution, in which two substrates are juxtaposed in the reaction chamber, the gas feed takes place between these juxtaposed substrates 2 and the gas discharge from the reaction chamber side walls surrounding the substrates. Thus the flow dynamics of the reaction chamber can be optimised. There may also be a plurality of substrates on the plate.

The feed and discharge connections are to be provided in the ALD reactor of the invention such that, despite the movement of the front plate 6, the cleanness and tightness of the connections are ensured. A solution for ensuring the tightness of the connections is to mount a completely sealed accordion or bellows pipe of metal between the inner wall of the low-pressure chamber 4 and the movable upper or lower plate. An accordion pipe of this kind is welded to flanges or other corresponding coupling parts that are further attached, by sealing with metal or elastomer, or by welding directly into place to a wall of the low-pressure chamber 4 or to the front plate 6. The connection is thus sealed stationary throughout and it may be provided, if the application or the low pressure zone so requires, completely with metal seals. Alternatively, the accordion pipe may be welded or otherwise tightly attached directly to the wall of the low-pressure chamber and/or to the front plate 6, whereby no separate sealing is needed. When the front plate 6 is moved in a reciprocating manner inside the low-pressure chamber 4, the accordion pipe extends or straightens out and contracts or wrinkles down elastically. In that case inside the low-pressure chamber 4 there will be no sliding, chafing, contacting or other relative movements resulting from lead-ins, which might let or produce impurities inside the low-pressure vessel.

In accordance with the above, a lead-in or connection in the low-pressure vessel implemented by means of an accordion or bellows-type pipe enables a simple and efficient solution, in which the front plate 6 of the reaction chamber is provided movable in relation to the low-pressure chamber 4. The accordion pipe retains tightness during and despite the movement of the movable front plate 6 and/or the support structure 8. By means of the accordion pipe it is possible to introduce gases into the low-pressure vessel and remove them therefrom, and in addition, electricity, thermometers and pressure gauges may be led in via these accordion connections and connected directly to the parts moving inside the low-pressure chamber 4. Inside the accordion pipe there may prevail normal atmospheric pressure, whereby wires and pipes mounted therein as well as other components to be applied inside the low-pressure chamber 4 may be at normal atmospheric pressure and at ambient temperature, and consequently they need not be provided to withstand low pressure or higher temperatures prevailing in the low-pressure vessel. Simultaneously, the accordion connection also enables combination and integration of trace heating of gas connections and lead-ins, when the trace heating is provided in connection with the accordion pipe. Trace heating refers here to the fact that the temperature of connections to be led through a cold wall of the vacuum vessel will be ensured, for instance with separate heaters, so as to avoid possible condensation.

Via the accordion pipe it is also possible to mount in the low-pressure chamber 4 lifting gear, by means of which the front plate 6 and/or the support structure 8 of the reaction chamber may be lifted and lowered. In the solution of FIGS. 1A, 1B and 2, in the corners of the front plate 6, or in the vicinity thereof, it is possible to provide lifting connections by means of accordion pipes such that the lifting members of the lifting gear, which move the front plate 6 within the low-pressure vessel, are introduced through the accordion pipes into the low-pressure chamber 4 and connected to the front plate 6. These lifting members of the lifting gear may be in the accordion pipe at the normal atmospheric pressure, whereby the low pressure of the low-pressure chamber 4 actually draws the front plate 6 upwardly towards the front plate 8 and the lifting gear is to be used for drawing the front plate 6 downwardly. In an embodiment of this kind, the lifting gear may operate by means of a spindle motor and/or a ball-race screw, for instance.

In the embodiment of FIGS. 1A, 1B and 2 the support structure 8 constitutes a support structure, against which the front plate 6 and/or the substrate 2 rest, when the reaction chamber is closed. In other words, the support structure 8 does not comprise any gas connections at all. Thus, in the embodiment described here only the substrate surface facing the front plate 6 is modified by means of the ALD method, because only the substrate surface facing the front plate 6 is exposed to gases. In an alternative solution, the front plate 6 and the support structure 8 could both be provided with gas connections such that both surfaces of the substrate 2, or alternatively, surfaces to be treated of two substrates placed back to back could be treated simultaneously and in the same manner or with the same starting materials, or in different manners and with different starting materials, whereby the support structure 8 would constitute the second front plate. In that case the support structure 8 could be similar to the front plate 6. Alternatively, the gas connections 10, 12 of the front plate 6 may be connected at least partly on the side of the support structure 8 or to the support structure 8 such that gas is conveyable and dischargeable also from the side of the support structure 8 of the substrate 2, even though the support structure 8 is not provided with gas connections. The support structure 8 may be, for instance, plane-like, or planar, or it may comprise support studs or the like support elements. In other words, the support structure may be any support capable of supporting the substrate or the substrate support.

The front plate 6 and/or the support structure 8 may be provided with seals, by means of which the reaction chamber can be sealed in the closed state. The seals may be O-rings, for instance. The seals may be placed in the front plate 6 and/or in the support structure 8 such that the seals are between the front plate 6 and the support structure 8 sealing them against one another. In that case the seals may only be provided in one of the front plate 6 and the support structure 8. Alternatively, the seals may be placed in the front plate 6 and/or the support structure 8 such that they rest against the substrate 2 or the substrate support. When high temperatures are used, the sealing of the reaction chamber may be solved without separate seals. In that case the even surfaces of the reaction chamber front plate 6 and/or of the support structure 8 are set against one other such that they come into contact with one another providing the sealing. Also in that case it is possible to seal the reaction chamber by placing at least the edge sections of the front plate 6 and/or the support structure 8 against the substrate 2 or the substrate support so as to provide the sealing.

Further, even though it is set forth above that the ALD reactor 1 or its low-pressure chamber 4 comprises only one reaction chamber, it is also possible to provide the low-pressure chamber 4 of the ALD reactor 1 with two or more reaction chambers. In a preferred solution these reaction chambers are positioned successively in the low-pressure chamber 4 such that a substrate 2 may be introduced into each reaction chamber simultaneously, whereby the capacity of the ALD reactor can be increased. Alternatively, each substrate may be introduced consecutively into these reaction chambers, whereby in each reaction chamber the substrate 2 is treated in a predetermined manner and with predetermined starting materials. In that case in one ALD reactor the substrate 2 may be subjected successively to a variety of surface growing or modifying processes.

In addition, the reaction chamber may be provided with a plasma electrode and/or a spray head or nozzle.

FIGS. 1A, 1B and 2 show an embodiment of the present invention, in which the ALD reactor 1 is provided such that it may placed to form a part of a production line, in which there are two or more successive process chambers for modifying and/or growing a surface of a substrate 2 and in which the substrate 2 is transferred horizontally through successive process chambers. Thus, the ALD reactor 1 is provided with a first gate arrangement 14, through which the substrate 2 is introduced into a low-pressure chamber 4, and with a second gate arrangement 1, through which the substrate 2 is removed from the low-pressure chamber 4. In the low-pressure chamber, and preferably throughout the production line, the substrate 2 is transferred in the horizontal direction. Within the low-pressure chamber 4 the substrate 2 is transferred by transfer means 18, on which the substrate 2 passes and onto which it is supported at the edge sections, and in particular; at the edge sections in parallel with the travel direction of the substrate 2, as shown in FIG. 2. In other words, by means of the transfer means 18 the substrate 2 is trans-ferrable horizontally through the low-pressure chamber 4.

In accordance with FIGS. 1A and 1B, inside the low-pressure chamber 4 there is provided a reaction chamber, which consists of a front plate 6, including gas connections 10, 12, and a support structure 8. In this embodiment the front plate 6 is placed beneath the substrate 2 and the support structure 8 is placed above the substrate 2, between which front plate 6 and support structure 8 the substrate may be sandwiched. Moreover, in accordance with FIGS. 1A, 1B and 2, the front plate 6 is arranged to move vertically and the support structure 8 is stationary such that the reaction chamber may be opened and closed by moving the front plate 6 in the direction of the arrow 20. Thus, the reaction chamber is opened by moving the front plate 6 away from the support structure 8 to the position shown in FIG. 2, where the front plate 6 and the support structure 8 are vertically at a distance from one another. In this open state of the reaction chamber as shown in FIG. 2 the front plate 6 is beneath the substrate 2 locating on the transfer means 18, or beneath the upper level defined by the transfer means 18, and between the tracks or rolls of the transfer means 18 that are in contact with the opposite edges of the substrate 2. As a stationary structure, the support structure 8, in turn, is placed at a predetermined height above the transfer means 18 and/or the substrate 2 locating on the transfer means 18.

In the embodiment of FIGS. 1A, 1B and 2, the substrate 2 may be transferred in horizontal direction through a first gate arrangement 14 and further between the front plate 6 of the open-state reaction chamber and the support structure 8 by the transfer means 18. The substrate 2 is further stopped in a position between the front plate 6 and the support structure 8, whereby the front plate 6 may be moved vertically upwards towards the support structure 8 such that, as the front plate 6 moves, it lifts the substrate upwards off the transfer means 18, whereby the substrate 2 is placed on the front plate 6. The front plate 6 is moved continuously upwards, until the front plate 6 or the substrate 2 is placed against the support structure 8, whereby the reaction chamber is in the closed state. In other words, with one linear movement of the front plate 6 the substrate 2 is lifted off the transfer means and the reaction chamber is closed such that the substrate 2 is placed, at least for the portion to be treated, inside the reaction chamber, as shown schematically in FIGS. 1A and 1B. When the reaction chamber is closed, it is possible to modify the substrate 2 by means of the ALD method. After treating the substrate 2 in the desired manner by means of the ALD method, the reaction chamber is opened by moving the front plate 6 vertically downwards, until the front plate has resumed its position, as shown in FIG. 2, beneath the upper surface of the transfer means 18 and the substrate 2 has at the same time taken its place on the transfer means 18. Thereafter, the substrate 2 may be further transferred onwards by the transfer means 18 and away from the low-pressure chamber 4 via a second gate arrangement 16. Thus, the loading of the substrate 2 into the reaction chamber and the closing of the reaction chamber, and correspondingly, the opening of the reaction chamber and the removal of the substrate 2 from the reaction chamber may be carried out with one linear movement, which in this embodiment is performed perpendicularly to the travel direction of the substrate 2.

The reaction chamber may also be provided such that the support structure 8 is placed below the substrate 2 and the front plate 6 is placed above the substrate 2, between which support structure 8 and front plate 6 the substrate may be placed. In addition, also the support structure 8 and the front plate 6 may be both arranged to move vertically such that the front plate 6 or the support structure 8 locating above the substrate may be lowered downwardly for closing the reaction chamber and lifted upwardly for opening the reaction chamber. In that case if it is only the front plate 6 or the support structure 8 above the substrate 2 that moves, and the front plate 6 or the support structure 8 beneath the substrate is stationary, the front plate 6 or the support structure 8 must be placed beneath the substrate 2 accurately on the same level with the upper surface of the transfer means 18. In an alternative solution both the front plate 6 and the support structure 8 are arranged to move vertically such that the reaction chamber may be closed by moving the front plate 6 and the support structure 8 towards one another and opened by moving them away from one another. This may be implemented in two ways: either the substrate may be lifted, as shown in FIGS. 1A and 1B, upwardly off the transfer means 18 by means of the support structure 8 or the front plate 6 locating beneath the substrate 2 and the support structure 8 or the front plate 6 locating above the substrate 2 may be moved downwardly at the same time, or first only the support structure 8 or the front plate 6 above the substrate 2 is moved, or the support structure 8 or the front plate 6 beneath the substrate 2 may be moved upwardly such that it is placed over the lower surface of the substrate 2 but does not lift the substrate 2 upwardly and the support structure 8 or the front plate 6 above the substrate 2 is lowered downwardly on the substrate 2 so as to close the reaction chamber.

In a simpler embodiment of the present invention, the reaction chamber comprises only one front plate 6, which is placed such that the substrate is transferrable above or below it. The front plate 6 placed above the substrate 2 may be lowered on the upper surface of the substrate 2 for closing the reaction chamber and lifted upwardly at a distance from the upper surface of the substrate 2 for opening the reaction chamber. Alternatively, the front plate 6 is placed beneath the substrate 2 and it may be lifted upwardly on the lower surface of the substrate 2 for closing the reaction chamber and it may be lowered downwardly at a distance from the lower surface of the substrate for opening the reaction chamber.

In another embodiment, two planar substrates 2, a first and a second substrate, are superimposed such that their surfaces are against one another. Thus, two substrates may be transferred and treated together. In this embodiment the ALD reactor comprises two front plates 6, a first and a second front plate, which are placed on the side of the first and the second substrates 2, respectively, at a distance from one another. The superimposed first and the second substrates 2 are transferred between the front plates 6 and the front plates 6 are moved onto the substrates so as to form reaction chambers. In that case the first substrate 2 forms the first reaction chamber with the first front plate 6 for treating the surface of the first substrate 2 facing the first front plate 6 and the second substrate 2 forms the second reaction chamber with the second front plate 6 for treating the surface of the second substrate 6 facing the second front plate 6. In this embodiment it is also possible to move the first and the second substrates together towards the first or the second front plate, whereby only the second front plate needs to be moved. This may be implemented, for instance, such that by means of the second front plate the first and the second substrates are moved such that the first stationary front plate will be placed over the first substrate.

In yet another embodiment, two substrates, the first and the second substrates, may be transferred one upon the other or side by side at a distance from one another. The ALD reactor may further comprise one front plate having a first side and a second side. The first and the second substrates are moved simultaneously in front of the first side and the second side of the front plate, respectively, for instance the first substrate in front of or above the first side of the front plate and the second substrate in front of or below the second side of the front plate. For closing the reaction chamber the first and the second substrates are moved such that the first and the second sides of the front plate will be placed over the first and the second substrates, respectively. Alternatively, for closing the reaction chamber it is possible to move the front plate and only one of the substrates. The front plate may be provided such that is forms two separate reaction chambers, one with the first substrate and another with the second substrate. The front plate may also be provided such that it forms only one reaction chamber, whereby the first and the second substrates both constitute a part of the reaction chamber together with the front plate.

With reference to the above, it is possible to implement the reaction chamber by utilizing the described constructional alternatives such that each solution will have an appropriate reaction chamber. In addition, it should be noted that the movement directions of the front plate 6 and the support structure 8 need not be vertical, but they may also move in some other direction, such as horizontal direction. Likewise, the movement direction of the substrate within the process chamber may be some other than the horizontal direction. For instance, the substrate may move vertically and the front plate and/or the support structure may move horizontally. In that case the substrate does not have an upper surface and a lower surface, but a first surface and a second surface, which correspond to the upper surface and the lower surface of the above described embodiments. In that case the substrate is transferred in front of or beside the front plate in the open state of the reaction chamber, in which the front plate is at a distance from the substrate, and the front plate and the substrate are moved with respect to one another for opening and closing the reaction chamber. In a preferred case, however, the plane-like substrate is transferred in the process chamber in the direction parallel to its surface and the front plate and/or the support structure in the direction perpendicular to this substrate surface, whereby the substrate is also lifted and lowered, or moved otherwise when loaded in the reaction chamber, by means of the front plate or the support structure perpendicularly to the substrate surface.

It is apparent to a person skilled in the art that as technology advances the basic idea of the invention may be implemented in a variety of ways. Thus, the invention and the embodiments thereof are not restricted to the above described examples, but they may vary within the scope of the claims.

1. An ALD reactor for treating one or more substrates, the ALD reactor comprising at least one reaction chamber including a front plate having gas connections for feeding starting materials, flushing gases and the like gases inside the reaction chamber, wherein
the front plate of the reaction chamber and a substrate are arranged to move linearly in relation to one another for placing the front plate over the substrate and closing the reaction chamber such that the substrate or the substrate support, to which the substrate is supported or attached constitutes a part of the reaction chamber when the reaction chamber is closed;
the front plate is arranged to move linearly for being placed at a distance from the substrate for opening the reaction chamber;
the substrate is arranged for being loaded beneath, above or in front of the front plate when the reaction chamber is in an open state, in which the front plate is at the distance from the substrate;
the substrate is treatable with the ALD method in the closed state of the reaction chamber, in which the front plate is placed over the substrate.

2. The ALD reactor of claim 1, wherein the front plate is arranged for being moved substantially in a vertical direction.

3. The ALD reactor of claim 1, wherein the front plate is arranged for being lowered from above the substrate on the upper surface of the substrate for closing the reaction chamber, or that the front plate is arranged for being lifted from beneath the substrate against the lower surface of the substrate for closing the reaction chamber.

4. The ALD reactor of claim 1, wherein the substrate is arranged for being moved substantially in a vertical direction.

5. The ALD reactor of claim 4, wherein the substrate is arranged for being lifted upwardly for placing the front plate on the upper surface of the substrate.

6. The ALD reactor of claim 1, wherein the front plate also includes gas connections for removing starting materials, flushing gases and the like gases from the reaction chamber.

7. The ALD reactor of claim 1, wherein the ALD reactor also comprises a support structure, which is placed on the opposite side of the substrate in relation to the front plate.

8. The ALD reactor of claim 7, wherein the support structure is arranged for being placed against the surface of the substrate, the substrate support or the front plate when the reaction chamber is in the closed state.

9. The ALD reactor of claim 1, wherein the support structure is arranged for being moved substantially vertically for opening and closing the reaction chamber.

10. The ALD reactor of claim 9, wherein the support structure is arranged for lifting the substrate upwardly for placing the front plate locating above the substrate onto the upper surface of the substrate.

11. The ALD reactor of claim 1, wherein the front plate or the support structure is fixed and provided stationary.

12. The ALD reactor of claim 8, wherein the support structure forms a second front plate in order to treat the opposite surfaces of the substrate when the reaction chamber is in the closed state.

13. The ALD reactor of claim 8, wherein the substrate support constitutes the support structure of the reaction chamber.

14. The ALD reactor of claim 1, wherein the substrate and/or the substrate support, to which the substrate is supported, constitutes a part of the reaction chamber, when the reaction chamber is in the closed state.

15. The ALD reactor of claim 14, wherein the front plate is concave such that in the closed state of the reaction chamber the front plate or the substrate and the substrate support placed over the upper surface or the lower surface of the substrate constitute the reaction space together with the front plate between the front plate and the substrate.

16. The ALD reactor of claim 1, wherein the reaction chamber is arranged to receive two or more substrates simultaneously.

17. The ALD reactor of claim 1, wherein the reaction chamber comprises a first and a second front plate, which in the open state of the reaction chamber are at a distance from one another for treating the opposite surfaces of the substrate in the closed state of the reaction chamber, in which the first and the second front plates are placed over the opposite surfaces of the substrate, respectively, or for treating the surface of the first or the second substrate placed one upon the other or face to face in the closed state of the reaction chamber, in which the first front plate is placed over the first substrate or the second front plate on the second substrate, respectively.

18. The ALD reactor claim 1, wherein the reaction chamber includes one front plate having a first and a second side, the first side of the front plate being arranged to be placed over the first substrate and the second side on the second substrate when the reaction chamber is in the closed state.

19. The ALD reactor of claim 18, wherein the front plate is arranged to form one reaction chamber with the first substrate and one reaction chamber with the second substrate, or that it is arranged to form one common reaction chamber with the first and the second substrates.

20. The ALD reactor of claim 1, wherein the front plate and/or the support structure and/or the substantially planar substrate are provided with a seal for sealing the reaction chamber in the closed state.

21. The ALD reactor of claim 1, wherein the ALD reactor also comprises a process chamber, inside which there is provided one or more reaction chambers.

22. The ALD reactor of claim 1, comprising a transfer means for loading the substrate beneath or above the front plate.

23. The ALD reactor of claim 22, wherein the front plate or the support structure arranged beneath the substrate is arranged to lift the substrate upwardly off the transfer means as the reaction chamber closes and to lower the substrate onto the transfer means as the reaction chamber opens.

24. The ALD reactor of claim 21, comprising one or more accordion and/or bellows-type pipe, which is provided tightly between a wall of the process chamber and the front plate and/or the support structure movable there inside so as to provide a lead-in into the process chamber.

25. The ALD reactor claim 24, wherein the accordion and/or bellows-type pipe is tightly attached, directly or through flanges, to the wall of the process chamber and, inside the low-pressure chamber, to the front plate and/or the support structure movable with respect to the process chamber.

26. A production line which comprises two or more successive process chambers for modifying and/or growing a surface of a substrate and where the substrate is transferred through successive process chambers, wherein at least one of the process chambers of the production line is provided to be an ALD reactor in accordance with claim 1.

27. A method for loading one or more substrates into a reaction chamber of an ALD reactor and for removing therefrom, wherein in the method a substrate is loaded into the reaction chamber for treatment;
by transferring the substrate above, beneath or in front of the front plate of the reaction chamber, the front plate including gas connection for feeding starting materials, flushing gases and the like gases into the reaction chamber; and
by moving the front plate of the reaction chamber and the substrate linearly in relation to one another for placing the front plate on the substrate in order to close the reaction chamber to the closed state, the substrate or a substrate support, to which the substrate is supported or attached constituting a part of the reaction chamber when the reaction chamber is closed;
and that in the method the substrate is removed from the reaction chamber;
by moving the front plate of the reaction chamber and the substrate linearly in relation to one another for placing the front plate and the substrate at a distance from one another in order to open the reaction chamber to the open state; and
by transferring the substrate away from above, below or in front of the front plate of the reaction chamber in the open state.

28. The method of claim 27, wherein the front plate or the substrate is moved substantially in vertical direction in relation to one another for opening and closing the reaction chamber.

29. The method of claim 27, wherein the front plate is moved downwardly onto the upper surface of the substrate in order to close the reaction chamber to the closed state.

30. The method of claim 27, wherein the front plate is moved upwardly onto the lower surface of the substrate in order to close the reaction chamber to the closed state.

31. The method of claim 27, whereby lifting the substrate upwardly for placing the front plate on the upper surface of the substrate in order to close the reaction chamber to the closed state.

32. The method of claim 27, whereby supporting the substrate, when the reaction chamber is in the closed state, with a support structure that is placed on the opposite side of the substrate with respect to the front plate.

33. The method of claim 32, whereby lifting the substrate upwardly by means of the support structure for placing the front plate on the upper surface of the substrate in order to close the reaction chamber to the closed state.

34. The method of claim 32, whereby lifting the substrate upwardly by means of the front plate by placing the front plate on the lower surface of the substrate for placing the upper surface of the substrate, the substrate support or the front plate, in turn, against the support structure.

35. The method of claim 32, whereby lowering the support structure downwardly against the upper surface of the substrate, the substrate support or the front plate in order to close the reaction chamber to the closed state.

36. The method of claim 27, wherein starting materials, flushing gases and the like gases are introduced into the reaction space of the reaction chamber and removed therefrom via the front plate.

37. The method of claim 27, wherein starting materials, flushing gases and the like gases are introduced into the reaction space of the reaction chamber and removed therefrom via the support structure, the support structure constituting the second front plate.

38. The method of claim 27, whereby loading two or more substrates into the reaction chamber simultaneously.

39. The method of claim 27, whereby transferring the substrate below or above the front plate by means of transfer means.

40. The method of claim 27, whereby lifting the substrate upwardly by means of the front plate or the support structure arranged therebelow off the transfer means as the reaction chamber closes and lowering the substrate onto the transfer means as the reaction chamber opens.

41. The method of claim 27, wherein the method is employed in a production line which comprises two or more successive process chambers for modifying and/or growing a surface of the substrate and where the substrate is transferred in horizontal direction through successive process chambers.
